(19) United States
(12) Patent Application Publication
(10) Pub. No.: US 2024/0179953 A1
(43) Pub. Date: May 30, 2024

(54) DISPLAY PANEL AND ELECTRONIC DEVICE

(71) Applicant: SHENZHEN CHINA STAR OPTOELECTRONICS SEMICONDUCTOR DISPLAY TECHNOLOGY CO., LTD, Shenzhen (CN)

(72) Inventors: Jiexin ZHENG, Shenzhen (CN); Weiran CAO, Shenzhen (CN); Wei LU, Shenzhen (CN); Quan CHENG, Shenzhen (CN)

(21) Appl. No.: 18/084,877

(22) Filed: Dec. 20, 2022

(30) Foreign Application Priority Data
Nov. 25, 2022 (CN) 202211494399.4

(51) Int. Cl. H10K 59/122; H10K 50/824; H10K 71/00

(52) U.S. Cl. CPC H01L 27/3246; H01L 51/5228; H01L 51/56; H01L 2227/323

(57) ABSTRACT

A display panel and an electronic device are provided. In the display panel, by disposing an auxiliary electrode in a first opening of a pixel definition layer, a first electrode is electrically connected to an auxiliary electrode line through the auxiliary electrode, so as to reduce a resistance of the first electrode. Therefore, uneven display due to voltage drop is remedied, so that a problem of large cathode resistance existing in a current display panel is relieved. Meanwhile, the first opening of the pixel definition layer of the present application exposes a part of a lateral wall of the auxiliary electrode. An organic light-emitting layer is cut off at a position of the first opening exposing the at least part of the lateral wall. The first electrode is electrically connected to the at least part of the lateral wall exposed by the organic light-emitting layer.

### CROSS REFERENCE TO RELATED APPLICATIONS

This application claims the benefit of priority of Chinese Application No. 202211494399.4 filed on Nov. 25, 2022. The contents of the above applications are all incorporated by reference as if fully set forth herein in their entirety.

### BACKGROUND OF INVENTION

### Field of Invention

The present application relates to the field of display technologies, and particularly relates to a display panel and an electronic device.

### Description of Prior Art

With development of display technology, display panels are developed toward directions of large sizes and high resolutions. However, with increment of sizes of the display panels, some defects not appearing in small and medium-sized display panels are gradually exposed. For example, when large-sized display panels are operated, they have a large resistance incurred by cathodes disposed in an entire surface, so that voltage drops (internal resistor (IR) drop) generate at different positions of the display panels, which leads to uneven brightness of the display panel.

### SUMMARY OF INVENTION

The present application provides a display panel and an electronic device to relieve the technical problem of large cathode resistance existing in the current display panels.

In order to solve the problems mentioned above, the present application provides the technical solutions as follows:

One embodiment of the present application provides a display panel, including:
a base substrate;
an auxiliary electrode line disposed on the base substrate;
a planarization layer disposed on a side of the auxiliary electrode line away from the base substrate;
an auxiliary electrode disposed on the planarization layer and electrically connected to the auxiliary electrode line;
a pixel definition layer disposed on the planarization layer, wherein a first opening is defined at a position corresponding to the auxiliary electrode in the pixel definition layer, and the first opening exposes at least part of a lateral wall of the auxiliary electrode;
an organic light-emitting layer covering a side of the pixel definition layer away from the planarization layer, and
being cut off at a position of the first opening exposing the at least part of the lateral wall, so as to expose the at least part of the lateral wall; and a first electrode covering on the organic light-emitting layer and electrically connected to the at least part of the lateral wall exposed by the organic light-emitting layer.

In the display panel provided by one embodiment of the present application, the auxiliary electrode includes at least one first conductive layer and at least one second conductive layer disposed in a stack, an orthogonal projection of one conductive layer of the first conductive layer and the second conductive layer being adjacent to each other on the base substrate is within a range of an orthogonal projection of another conductive layer on the base substrate.

In the display panel provided by one embodiment of the present application, the auxiliary electrode comprises at least one third conductive layer, the auxiliary electrode further includes at least one third conductive layer, the auxiliary electrode comprises at least one third conductive layer, the auxiliary electrode comprises at least one third conductive layer, the second conductive layer is located between the first conductive layer and the third conductive layer, an orthogonal projection of one conductive layer of the second conductive layer and the third conductive layer being adjacent to each other on the base substrate is within a range of an orthogonal projection of another conductive layer on the base substrate.

In the display panel provided by one embodiment of the present application, the auxiliary electrode comprises the first conductive layer, the second conductive layer, and the third conductive layer disposed in a stack, the second conductive layer is located on a side of the first conductive layer away from the planarization layer, and an orthogonal projection of the first conductive layer on the base substrate is within a range of an orthogonal projection of the second conductive layer on the base substrate.

In the display panel provided by one embodiment of the present application, a material of the first conductive layer and a material of the third conductive layer include indium tin oxide (ITO) or indium doped zinc oxide (IZO), and a material of the second conductive layer includes silver (Ag).

In the display panel provided by one embodiment of the present application, the auxiliary electrode includes the first conductive layer, the second conductive layer, and the third conductive layer disposed in a stack, the second conductive layer is located on a side of the first conductive layer away from the planarization layer, and an orthogonal projection of the second conductive layer on the base substrate is within a range of an orthogonal projection of the third conductive layer on the base substrate.

In the display panel provided by one embodiment of the present application, a material of the first conductive layer and a material of the third conductive layer include indium tin oxide (ITO) or indium doped zinc oxide (IZO), and a material of the second conductive layer includes aluminum (Al), tungsten oxide (WOx), or an aluminum alloy.

In the display panel provided by one embodiment of the present application, a slope angle of the lateral wall is greater than or equal to 90 degrees.

In the display panel provided by one embodiment of the present application, an orthogonal projection of the auxiliary electrode on the base substrate separates from an orthogonal projection of the pixel definition layer on the base substrate.

In the display panel provided by one embodiment of the present application, the display panel further includes a second electrode disposed on the planarization layer, the organic light-emitting layer is located between the second electrode and the first electrode, and the second electrode and the auxiliary electrode are disposed in a same layer.

In the display panel provided by one embodiment of the present application, the display panel further includes a transistor disposed on the base substrate, the second electrode is located on a side of the transistor away from the base substrate, the second electrode is electrically connected to the transistor, and the transistor includes an active layer, a gate electrode, a source electrode, and a drain electrode; and
wherein the display panel further includes a bridge electrode, the auxiliary electrode is electrically connected to the auxiliary electrode line through the bridge electrode, and the bridge electrode and at least one of the active layer, the gate electrode, the source electrode, or the drain electrode are disposed in a same layer.

In the display panel provided by one embodiment of the present application, the display panel further includes a light-shielding layer disposed on the base substrate, the light-shielding layer is located between the transistor and the base substrate and is disposed corresponding to the active layer, and the auxiliary electrode line and the light-shielding layer are disposed in a same layer.

One embodiment of the present application further provides an electronic device, which includes a housing and the display panel of one of the aforesaid embodiments. The display panel is assembled in the housing.

Beneficial effects of the present application: In the display panel and the electronic device provided by the present application, by disposing the auxiliary electrode is in the first opening of the pixel definition layer, the first electrode is electrically connected to the auxiliary electrode line through the auxiliary electrode, so as to reduce a resistance of the first electrode. Therefore, uneven display due to voltage drop is remedied, so that a problem of large cathode resistance existing in a current display panel is relieved. Meanwhile, the first opening of the pixel definition layer of the present application exposes the part of the lateral wall of the auxiliary electrode. The organic light-emitting layer is cut off at the position of the first opening exposing the at least part of the lateral wall, so as to expose the at least part of the lateral wall. The first electrode is electrically connected to the at least part of the lateral wall exposed by the organic light-emitting layer. Therefore, the first electrode is able to be directly contacted to and be electrically connected to the lateral wall of the auxiliary electrode, thereby reducing a contact resistance between the first electrode and the auxiliary electrode, and further remedying uneven display due to voltage drop.

### DESCRIPTION OF DRAWINGS

In order to more clearly illustrate embodiments or the technical solutions of the present application, the accompanying figures of the present application required for illustrating embodiments or the technical solutions of the present application will be described in brief. Obviously, the accompanying figures described below are only part of the embodiments of the present application, from which those skilled in the art can derive further figures without making any inventive efforts.

FIG. 1 is a schematic diagram of a sectional structure of a display panel provided by one embodiment of the present application.

FIG. 2 is a top-viewed structural schematic diagram of a positional relation of a pixel definition layer and an auxiliary electrode provided by one embodiment of the present application.

FIG. 3 is a schematic diagram of another sectional structure of the display panel provided by one embodiment of the present application.

FIG. 4 is a schematic diagram of still another sectional structure of the display panel provided by one embodiment of the present application.

FIG. 5 is a schematic diagram of a detailed structure at M in FIG. 4.

FIG. 6 is another top-viewed structural schematic diagram of a positional relation of the pixel definition layer and the auxiliary electrode provided by one embodiment of the present application.

FIG. 7 is a schematic diagram of a sectional structure of the auxiliary electrode provided by one embodiment of the present application.

FIG. 8 is a schematic diagram of another sectional structure of the auxiliary electrode provided by one embodiment of the present application.

FIG. 9 is a flowchart of a manufacturing method of the display panel provided by one embodiment of the present application.

FIG. 10 to FIG. 15 are schematic diagrams of part film layer structures of the display panel manufactured by each step in the manufacturing method of the display panel provided by embodiments of the present application.

### DETAILED DESCRIPTION OF EMBODIMENTS

The descriptions of embodiments below refer to accompanying drawings in order to illustrate certain embodiments which the present application can implement. The directional terms of which the present application mentions, for example, “top”, “bottom”, “upper”, “lower”, “front”, “rear”, “left”, “right”, “inside”, “outside”, “side”, etc., only refer to directions of the accompanying figures. Therefore, the used directional terms are for illustrating and understanding the present application, but not for limiting the present application. In the figures, units with similar structures are indicated by the same reference numerals. In the drawings, the thicknesses of layers and regions are exaggerated for clarity. The dimensions and thickness of each component shown in the accompanying figures are arbitrarily shown, present application is not limited thereto.

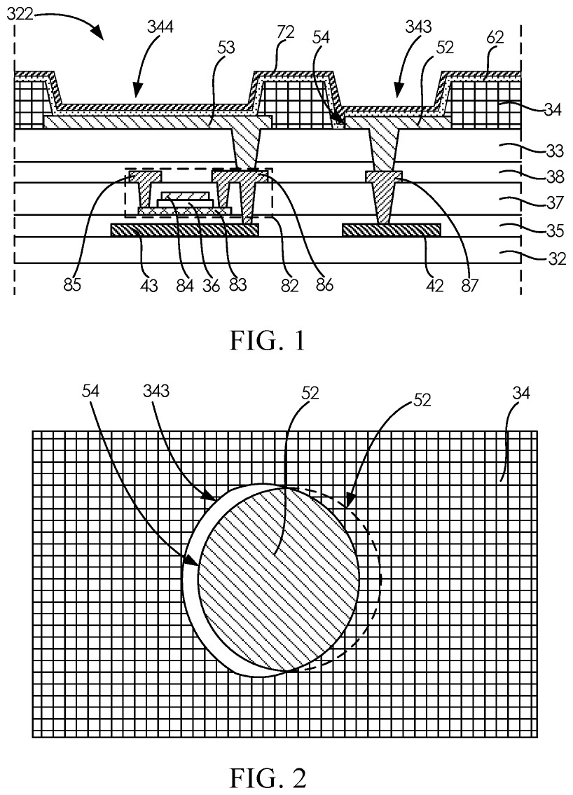

Please refer to FIG. 1 to FIG. 2. FIG. 1 is a schematic diagram of a sectional structure of a display panel provided by one embodiment of the present application. FIG. 2 is a top-viewed structural schematic diagram of a positional relation of a pixel definition layer and an auxiliary electrode provided by one embodiment of the present application. The display panel 100 includes a base substrate 10, and an auxiliary electrode line 20, a planarization layer 11, an auxiliary electrode 30, a pixel definition layer 12, an organic light-emitting layer 40, and a first electrode 50 disposed on the base substrate 10.

Specifically, the planarization layer 11 is disposed on a side of the auxiliary electrode line 20 away from the base substrate 10. The auxiliary electrode 30 is disposed on the planarization layer 11 and is electrically connected to the auxiliary electrode line 20. The pixel definition layer 12 is disposed on the planarization layer 11, and a first opening 121 is defined at a position corresponding to the auxiliary electrode 30 in the pixel definition layer 12. The first opening 121 exposes at least part of a lateral wall 32 of the auxiliary electrode 30. The organic light-emitting layer 40 covers a side of the pixel definition layer 12 away from the planarization layer 11, and is cut off at the position of the first opening 121 exposing the at least part of the lateral wall 32 of the auxiliary electrode 30, so as to expose the at least part of the lateral wall 32 of the auxiliary electrode 30. The first electrode 50 covers on the organic light-emitting layer 40 and is electrically connected to the at least part of the lateral wall 32 exposed by the organic light-emitting layer 40.

In this embodiment, by disposing the auxiliary electrode 30 in the first opening 121 of the pixel definition layer 12, the auxiliary electrode 50 is electrically connected to the auxiliary electrode line 20 through the auxiliary electrode 30, so as to reduce a resistance of the first electrode 50. Therefore, voltage drop of the first electrode 50 is reduced, so that uneven display due to the voltage drop is remedied, and a problem of large cathode resistance existing in a current display panel is relieved. Meanwhile, the first opening 121 exposes the at least part of the lateral wall 32 of the auxiliary electrode 30, and the organic light-emitting layer 40 is cut off at the at least part of the lateral wall 32 of the auxiliary electrode 30, so that the first electrode 50 is made to be directly contacted to and be electrically connected to the at least part of the lateral wall 32 exposed by the organic light-emitting layer 40. Therefore, a contact resistance between the first electrode 50 and the auxiliary electrode 30 is reduced, the voltage drop of the first electrode 50 is further reduced, so as to further remedy uneven display due to the voltage drop.

Optionally, as illustrated in FIG. 1, the first opening 121 exposes at least part of the lateral wall 32 of the auxiliary electrode 30. The first opening 121 exposes the at least part of the lateral wall 32 located at a side of the auxiliary electrode 30 close to a corresponding second opening 122.

Specifically, please refer to FIG. 1 and FIG. 2. The first opening 121 of the pixel definition layer 12 exposes the at least part of the lateral wall 32 of the auxiliary electrode 30. The pixel definition layer 12 further covers a part of the auxiliary electrode 30, so that an orthogonal projection of the auxiliary electrode 30 on the base substrate 10 and an orthogonal projection of the pixel definition layer 12 on the base substrate 10 have an overlapping region. Furthermore, the orthogonal projection of the auxiliary electrode 30 on the base substrate 10 and the orthogonal projection of the pixel definition layer 12 on the base substrate 10 further have a non-overlapping region, i.e., at least part of the non-overlapping region of the orthogonal projection of the auxiliary electrode 30 on the base substrate 10 and the orthogonal projection of the pixel definition layer 12 on the base substrate 10 is presence.

The organic light-emitting layer 40 is cut off at the position of the first opening 121 exposing the at least part of the lateral wall 32, so as to expose the at least part of the lateral wall 32. The first electrode 50 is electrically connected to the at least part of the lateral wall 32 exposed by the organic light-emitting layer 40. Therefore, the first electrode 50 is able to be directly contacted to and be electrically connected to the lateral wall 32 of the auxiliary electrode 30, so as to reduce a contact resistance between the first electrode 50 and the auxiliary electrode 30, thereby remedying uneven display due to voltage drop.

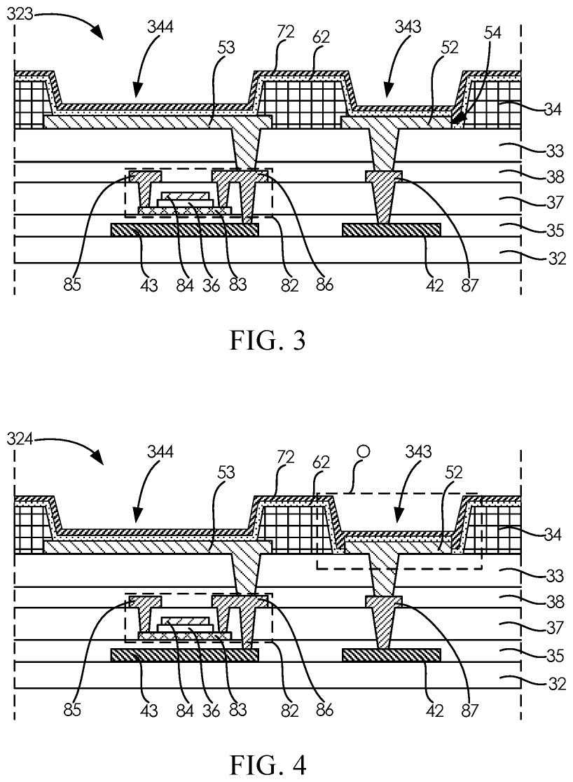

In one embodiment, please refer to FIG. 1 to FIG. 3. FIG. 3 is a schematic diagram of another sectional structure of the display panel provided by one embodiment of the present application. The difference from the aforesaid embodiments is that in the display panel 101 of this embodiment, as illustrated in FIG. 3, the first opening 121 exposes a part of the lateral wall 32 of the auxiliary electrode 30. The part of the lateral wall 32 exposed by the first opening 121 is located at a side of the auxiliary electrode 30 away from the corresponding second opening 122. In this way, the contact resistance between the first electrode 50 and the auxiliary electrode 30 can also be reduced, so as to remedy uneven display due to voltage drop.

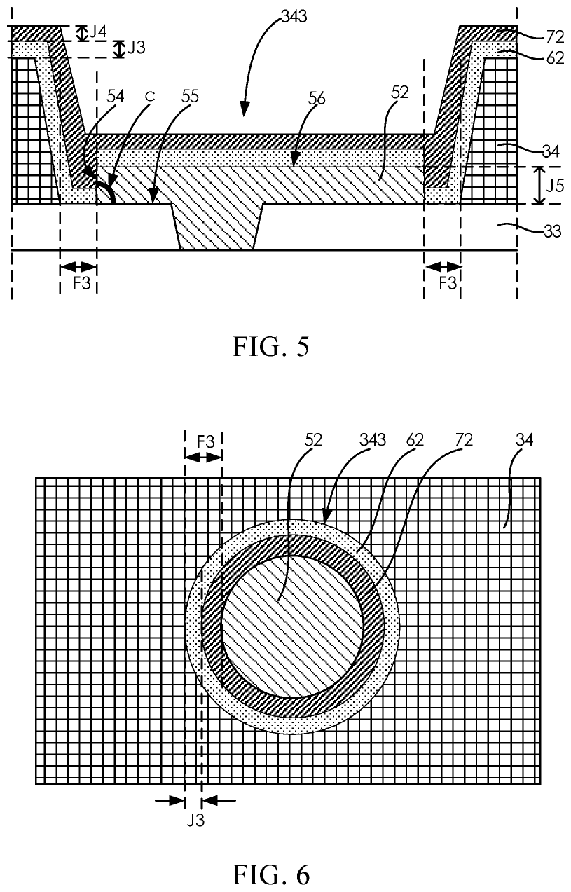

In one embodiment, please refer to FIG. 1 to FIG. 6. FIG. 4 is a schematic diagram of still another sectional structure of the display panel provided by one embodiment of the present application. FIG. 5 is a schematic diagram of a detailed structure at M in FIG. 4. FIG. 6 is another top-viewed structural schematic diagram of a positional relation of the pixel definition layer and the auxiliary electrode provided by one embodiment of the present application. The difference from the aforesaid embodiments is that in the display panel 102 of this embodiment, the first opening 121 exposes all the lateral wall 32 of the auxiliary electrode 30, the first electrode 50 is directly contacted to all the lateral wall 32 of the auxiliary electrode 30, so as to increase a direct contact area of the first electrode 50 and the auxiliary electrode 30, to further reduce the contact resistance between the first electrode 50 and the auxiliary electrode 30, and to further remedy uneven display due to the voltage drop.

Specifically, as illustrated in FIG. 4, an orthogonal projection of the auxiliary electrode 30 on the base substrate 10 separates from an orthogonal projection of the pixel definition layer 12 on the base substrate 10, so as to make the first opening 121 expose all the lateral wall 32 of the auxiliary electrode 30. Wherein, “separates from” means there is no overlapping portion between the two orthogonal projections. Specifically, there is no overlapping portion between the orthogonal projection of the auxiliary electrode 30 on the base substrate 10 and the orthogonal projection of the pixel definition layer 12 on the base substrate 10, i.e., the first opening 121 of the pixel definition layer 12 exposes the entire auxiliary electrode 30, so that the pixel definition layer 12 does not contact to the auxiliary electrode 30. Therefore, there is a gap between the auxiliary electrode 30 and the pixel definition layer 12. The presence of the gap exposes all the lateral wall 32 of the auxiliary electrode 30, so that the first electrode 50 can directly contact to all of the lateral wall 32 of the auxiliary electrode 30.

Please refer to FIG. 5. The lateral wall 32 of the auxiliary electrode 30 refers to a side of the auxiliary electrode 30 facing toward the pixel definition layer 12, i.e., the auxiliary electrode 30 is close to a side close to the pixel definition layer 12. In addition, a lower surface 33 of the auxiliary electrode 30 refers to a surface of the auxiliary electrode 30 contacting to the planarization layer 11, an upper surface 34 of the auxiliary electrode 30 refers to a surface of the auxiliary electrode 30 away from the planarization layer 11, and the upper surface 34 and the lower surface 33 are opposite to each other. The lateral wall 32 is located between the upper surface 34 and the lower surface 33 and surrounds the upper surface 34 and the lower surface 33. The first opening 121 exposes the lateral wall 32 and the upper surface 34 of the auxiliary electrode 30.

The following will take the display panel 102 as an example to describe in detail the structure of each part of the display panel in this application and how to realize the electrical connection that the first electrode 50 directly contacts to the auxiliary electrode 30.

Please continue referring to FIG. 4, in order to realize light emission of the display panel 102, the display panel 102 further includes a second electrode 31 disposed on the planarization layer 11. The second opening 122 is defined at a position corresponding to the second electrode 31 in the pixel definition layer 12. The second opening 122 exposes a part of the second electrode 31, i.e., the pixel definition layer 12 further covers an edge of the second electrode 31. The organic light-emitting layer 40 is located between the second electrode 31 and the first electrode 50, and the organic light-emitting layer 40 emits light under a mutual effect of the first electrode 50 and the second electrode 31. The first electrode 50 is a cathode, and the second electrode 31 is an anode.

Optionally, the organic light-emitting layer 40 includes a light-emitting unit, and a hole transport layer and an electron transport layer located on both sides of the light-emitting unit. Of course, the organic light-emitting layer 40 can further include a hole injection layer and an electron injection layer. Wherein, the hole injection layer and the hole transport layer are located between the second electrode 31 and the light-emitting unit, and the electron injection layer and the electron transport layer are located between the first electrode 50 and the light-emitting unit.

The hole injection layer receives the holes transmitted by the second electrode 31. The holes are transmitted to the light-emitting unit through the hole transport layer. The electron injection layer receives the electrons transmitted by the first electrode 50. The electrons are transmitted to the light-emitting unit through the electron transport layer. The holes and the electrons combine at positions of the light-emitting unit to generate excitons. The excitons transit from an excited state to a ground state to release energy and emit light.

Optionally, the second electrode 31 and the auxiliary electrode 30 are disposed in a same layer, so that the auxiliary electrode 30 is closer to the first electrode 50, so as to reduce difficulty of the first electrode 50 contacting to the auxiliary electrode 30. Wherein, “disposing in a same layer” in the present application refers to a film layer formed of a same material is patterned to obtain at least two different features in manufacturing processes, so the at least two different features are configured in the same layer. For example, the second electrode 31 and the auxiliary electrode 30 in this embodiment are obtained by performing a patterning process on a same conductive film layer, and the second electrode 31 and the auxiliary electrode 30 are disposed in a same layer.

Optionally, a material of the second electrode 31 and the auxiliary electrode 30 include transparent conductive materials such as indium tin oxide (ITO), indium zinc oxide (IZO), ZnO or In₂O₃; or Al, an Al alloy (e.g., ANCL), a metal or an alloy such as silver (Ag), tungsten oxide (WOx).

It can be understood that the organic light-emitting layer 40 is usually manufactured into an entire surface, so that the manufactured organic light-emitting layer 40 can cover the pixel definition layer 12 and the first opening 121 and the second opening 122 in the pixel definition layer 12. For example, the organic light-emitting layer 40 can cover the second electrode 31 in the second opening 122 and the auxiliary electrode 30 in the first opening 121. However, the organic light-emitting layer 40 covering the auxiliary electrode 30 can lead to the first electrode 50 be difficult to directly contact to the auxiliary electrode 30.

In this way, in this embodiment, by making the pixel definition layer 12 not covering the edge of the auxiliary electrode 30, the pixel definition layer 12 is disposed separated from the auxiliary electrode 30, so as to expose the lateral wall 32 of the auxiliary electrode 30, which provides possibility for the first electrode 50 to directly contact to the auxiliary electrode 30. However, due to entire-surface coverage of the organic light-emitting layer 40, in order to realize the direct contact between the first electrode 50 and the lateral wall 32 of the auxiliary electrode 30, the organic light-emitting layer 40 needs to be cut off at the position of the lateral wall 32 of the auxiliary electrode 30, so that the organic light-emitting layer 40 does not completely cover the lateral wall 32 of the auxiliary electrode 30.

Optionally, in order to make the organic light-emitting layer 40 be cut off at the lateral wall 32 of the auxiliary electrode 30, the slope angle “a” of the edge of the auxiliary electrode 30 close to the pixel definition layer 12 can be greater than or equal to 90 degrees, i.e., the slope angle “a” of the lateral wall 32 of the auxiliary electrode 30 is greater than or equal to 90 degrees, so that the lateral wall 32 of the auxiliary electrode 30 forms a steep slope (high taper) or forms an undercut structure. In this way, when the organic light-emitting layer 40 covers the auxiliary electrode 30, as the edge of the auxiliary electrode 30 has the steep slope or the undercut structure, the organic light-emitting layer 40 is made to be cut off at the edge of the auxiliary electrode 30 to expose the edge of the auxiliary electrode 30, i.e., the lateral wall 32 of the auxiliary electrode 30 is exposed.

It should be noted that, the “slope angle a” of the edge of the auxiliary electrode 30 refers to an included angle between the lateral wall 32 of the auxiliary electrode 30 and the lower surface 33 of the auxiliary electrode 30, when the slope angle “a” of the edge of the auxiliary electrode 30 is greater than 90 degrees, the edge of the auxiliary electrode 30 forms the undercut structure. Of course, the slope angle “a” of the edge of the auxiliary electrode 30 of the present application is not limited to be greater than or equal to 90 degrees, the slope angle “a” can also be less than 90 degrees, but the slope angle “a” needs to be ensured close to 90 degrees. For example, the slope angle “a” is 89 degrees. At this time, the edge of the auxiliary electrode 30 can still form the steep slope, and the organic light-emitting layer 40 can also be cut off at this position.

It can be understood that, in order to ensure that the organic light-emitting layer 40 is cut off at the lateral wall 32 of the auxiliary electrode 30 and to expose the lateral wall 32 of the auxiliary electrode 30, a thickness H3 of the auxiliary electrode 30 needs to be ensured to be greater than a thickness H1 of the organic light-emitting layer 40. For example, the thickness H3 of the auxiliary electrode 30 is greater than 1000 angstroms, and the thickness H1 of the organic light-emitting layer 40 ranges from 100 angstroms to 500 angstroms. Wherein, “thickness” in the present application refers to the manufactured thickness of each film layer itself. For example, the thickness H1 of the organic light-emitting layer 40 refers to the thickness of the manufactured organic light-emitting layer 40 covering on other film layers.

Of course, if the thickness H3 of the auxiliary electrode 30 is much greater than the thickness H1 of the organic light-emitting layer 40, when the organic light-emitting layer 40 is cut off at the lateral wall 32 of the auxiliary electrode 30, the larger an exposed area of the auxiliary electrode 30 is. For example, the thickness H3 of the auxiliary electrode 30 is 1200 angstroms, and the thickness H1 of the organic light-emitting layer 40 is 100 angstroms. In this way, the contact area between the first electrode 50 and the auxiliary electrode 30 can also be larger, which is more conducive to improving reliability of the electrical connection between the first electrode 50 and the auxiliary electrode 30, and reducing the contact resistance of the first electrode 50 and the auxiliary electrode 30.

In addition, in order to ensure that there is enough space between the auxiliary electrode 30 and the pixel definition layer 12 for the first electrode 50 directly contacting to the auxiliary electrode 30, a gap distance D1 between the auxiliary electrode 30 and the pixel definition layer 12 needs to be at least greater than the thickness H1 of the organic light-emitting layer 40. Preferably, the gap distance D1 between the auxiliary electrode 30 and the pixel definition layer 12 is greater than or equal to a sum of the thickness H2 of the organic light-emitting layer 40 and the first electrode 50.

In this way, there is enough space between the pixel definition layer 12 and the auxiliary electrode 30 layer for the first electrode 50 to directly contact to the lateral wall 32 of the auxiliary electrode 30. As illustrated in FIG. 6, the first electrode 50 directly contacts to the entire edge of the auxiliary electrode 30. In FIG. 6, the first opening 121 of the pixel definition layer 12 is shown as a circular hole, but the shape of the first opening 121 in the present application, for example, the shape of the first opening 121 can also be a square or other irregular shape. The surface shape of the auxiliary electrode 30 is adapted to the shape of the first opening 121. For example, if the first opening 121 is a circular hole, the surface shape of the auxiliary electrode 30 is circular.

Furthermore, in order to provide a driving signal to the second electrode 31, the display panel 102 further includes a transistor 60 disposed on the base substrate 10. The second electrode 31 is located on a side of the transistor 60 away from the base substrate 10, and the second electrode 31 is electrically connected to the transistor 60.

Optionally, the base substrate 10 can be a rigid substrate or a flexible substrate. When the base substrate 10 is the rigid substrate, it can include a rigid substrate such as a glass substrate. When the base substrate 10 is the flexible substrate, it can include flexible substrates such as a polyimide (PI) film, an ultra-thin glass film, etc. Of course, in order to improve a performance of the base substrate 10 preventing moisture or oxygen from penetrating, a structure of a single-layer or a multi-layer buffer layer 13 including silicon oxide or silicon nitride can also be disposed between the base substrate 10 and the transistor 60. The buffer layer 13 can prevent unwanted impurities or pollutants (e.g., moisture, oxygen, etc.) from diffusing from the base substrate 10 into a device that can be damaged by these impurities or pollutants, while can also provide a flat top surface.

The thin film transistor layer 60 is disposed on the base substrate 10. The transistor 60 includes an active layer 61, a gate electrode 62, a source electrode 63, and a drain electrode 64. The second electrode 31 is electrically connected to the source electrode 63 or the drain electrode 64 of the transistor 60. In one embodiment of the present application, electrical connection between the second electrode 31 and the drain 64 is taken as an example for description.

In order to prevent the active layer 61 of the transistor 60 from being irradiated by light and affecting the performance of the transistor 60, the display panel 102 further includes a light-shielding layer 21. The light-shielding layer 21 is disposed corresponding to the active layer 61 of the transistor 60 to shield the active layer 61, while the light-shielding layer 21 is also electrically connected to the drain electrode 64 of the transistor 60 to realize a better light-shielding effect.

Optionally, the light-shielding layer 21 and the auxiliary electrode line 20 are disposed in a same layer. At this time, a distance between the auxiliary electrode line 20 and the auxiliary electrode 30 is relatively long. In order to realize electrical connection between the auxiliary electrode 30 and the auxiliary electrode line 20 and to reduce process difficulty of defining a deep contact hole, the auxiliary electrode 30 can be electrically connected to the auxiliary electrode trace 20 through the bridge electrode 65. The bridge electrode 65 and at least one of the active layer 61, the gate electrode 62, the source electrode 63, or the drain electrode 64 are disposed in a same layer. In one embodiment of the present application, the bridge electrode 65, the source electrode 63, and the drain electrode 64 disposed in a same layer is taken as an example.

Specifically, the light-shielding layer 21 and the auxiliary electrode line 20 are disposed on the base substrate 10. The buffer layer 13 covers on the light-shielding layer 21, the auxiliary electrode 30, and the base substrate 10. The active layer 61 is disposed on the buffer layer 13. The gate insulation layer 14 is disposed on a side of the active layer 61 away from the buffer layer 13. The gate electrode 62 is disposed on the gate insulation layer 14, and the gate electrode 62 is disposed corresponding to a channel of the active layer 61.

The interlayer insulation layer 15 covers the gate electrode 62 and the buffer layer 13. The source electrode 63, the drain electrode 64, and the bridge electrode 65 are disposed on the interlayer insulation layer 15. The source electrode 63 is electrically connected to a source region of the active layer 61. The drain electrode 64 is electrically connected to a drain region of the active layer 61, while the drain electrode 64 is also electrically connected to the light-shielding layer 21. The bridge electrode 65 is electrically connected to the auxiliary electrode line 20. Wherein, the source region and the drain region of the active layer 61 are respectively located on two opposite sides of the channel of the active layer 61.

The passivation layer 16 covers the source electrode 63, the drain electrode 64, the bridge electrode 65, and the interlayer insulation layer 15. The planarization layer 11 covers the passivation layer 16. The first electrode 50 and the auxiliary electrode 30 are disposed on the planarization layer 11, the first electrode 50 is electrically connected to the drain electrode 64, and the auxiliary electrode 30 is electrically connected to the bridge electrode 65, so as to realize electrical connection between the auxiliary electrode 30 and the auxiliary electrode line 20, thereby realizing the electrical connection between the first electrode 50 and the auxiliary electrode line 20. Through the parallel connection of the first electrode 50 and the auxiliary electrode line 20, the resistance of the first electrode 50 is reduced, and the voltage drop of the first electrode 50 is reduced.

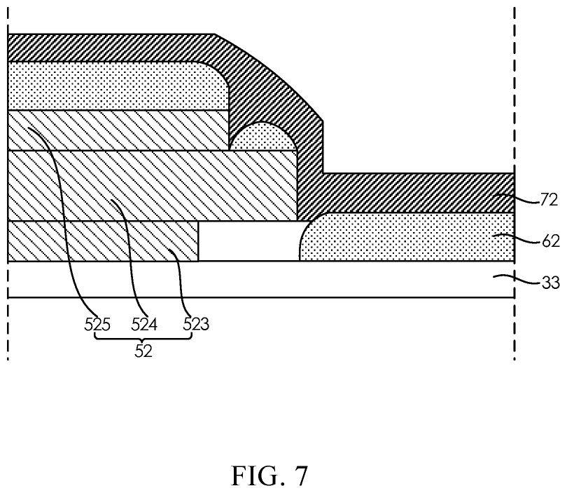

In one embodiment, please refer to FIG. 1 to FIG. 7. FIG. 7 is a schematic diagram of a sectional structure of the auxiliary electrode provided by one embodiment of the present application. The difference from the aforesaid embodiments is that the auxiliary electrode 30 includes at least one first conductive layer 301 and at least one second conductive layer 302 disposed in a stack, and an orthogonal projection of one conductive layer of the first conductive layer 301 and the second conductive layer 302 being adjacent to each other on the base substrate 10 is within a range of an orthogonal projection of another conductive layer on the base substrate 10.

It should be noted that, in the present application, one orthogonal projection being within the range of another orthogonal projection means that one orthogonal projection partially overlaps with another orthogonal projection, an area of one orthogonal projection is smaller than an area of another orthographic projection, and there is a gap between the two orthogonal projections. For example, an orthogonal projection of one conductive layer of the first conductive layer 301 and the second conductive layer 302 being adjacent to each other on the base substrate 10 being within a range of an orthogonal projection of another conductive layer on the base substrate 10 means that the orthogonal projection of one of the two adjacent conductive layers overlaps with the orthogonal projection of another conductive layer, the area of the orthogonal projection of one conductive layer is smaller than the area of another conductive layer, and there is a gap between the orthogonal projections of the two conductive layers.

A relation between the orthogonal projections of the adjacent first conductive layer 301 and second conductive layer 302 is determined by a positional relation and a dimensional relation between the adjacent first conductive layer 301 and second conductive layer 302. That is, reflection of the relation of the orthogonal projections of two adjacent conductive layers in the two conductive layers themselves is: outer boundaries of the adjacent first conductive layer 301 and second conductive layer 302 are not flush with each other, and the outer boundary of one conductive layer exceeds beyond the outer boundary of another conductive layer, so that protrusions, burrs, or undercut structures presents on an edge appearance of the auxiliary electrode 30. Preferably, the boundary of the conductive layer away from the planarization layer 11 exceeds beyond the boundary of the conductive layer close to the planarization layer 11.

Therefore, comparing to the edge appearance of the auxiliary electrode 30 with the single-layer structure, the edge appearance of the auxiliary electrode 30 with the multi-layer structure is more complex and changeable, which is more conducive to the organic light-emitting layer 40 being cut off at the edge of the auxiliary electrode 30, so that it is easier to realize the direct contact between the first electrode 50 and the auxiliary electrode 30. Furthermore, the complexity of the edge appearance of the auxiliary electrode 30 also makes the cut-off area of the organic light-emitting layer 40 be larger at the edge of the auxiliary electrode 30, so that the exposed area of the auxiliary electrode 30 is also larger. Therefore, the direct contact area between the first electrode 50 and the auxiliary electrode 30 is increased, so that the contact resistance between the first electrode 50 and the auxiliary electrode 30 can be further reduced, and the voltage drop of the first electrode 50 can be reduced.

In order to further increase complexity of the edge appearance of the auxiliary electrode 30, the auxiliary electrode 30 further includes at least one third conductive layer 303. The second conductive layer 302 is located between the first conductive layer 301 and the third conductive layer 303. An orthogonal projection of one conductive layer of the second conductive layer 302 and the third conductive layer 303 being adjacent to each other on the base substrate 10 is within a range of an orthogonal projection of another conductive layer on the base substrate 10.

The edge appearance of the auxiliary electrode 30 will be described in detail below with specific examples.

Optionally, as illustrated in FIG. 7, the auxiliary electrode 30 includes the first conductive layer 301, the second conductive layer 302, and the third conductive layer 303 disposed in a stack, the second conductive layer 302 is located on a side of the first conductive layer 301 away from the planarization layer 11, and an orthogonal projection of the first conductive layer 301 on the base substrate 10 is within a range of an orthogonal projection of the second conductive layer 302 on the base substrate 10.

Specifically, an outer boundary of the second conductive layer 302 exceeds the outer boundary of the first conductive layer 301 and the third conductive layer 303, so that protrusions or burrs present in the edge appearance of the auxiliary electrode 30, thereby making the organic light-emitting layer 40 to be more easily cut off at the edge of the auxiliary electrode 30. From another perspective, it can be understood that the appearance of the protrusions or the burrs formed on the edge of the auxiliary electrode 30 is actually equivalent to an undercut structure. It should be noted that FIG. 7 only shows the edge appearance of one side of the auxiliary electrode 30, and edge appearances of other sides of the auxiliary electrode 30 can refer to FIG. 7.

Of course, in another embodiment, the outer boundary of the third conductive layer 303 can also exceed the outer boundary of the second conductive layer 302, so that the protrusions or burrs formed on the edge of the auxiliary electrode 30 are more prominent, or the entire auxiliary electrode 30 is allowed to have a larger undercut structure, which makes the edge appearance of the auxiliary electrode 30 be more complicated.

Optionally, the edge appearance of the auxiliary electrode 30 can be formed by choosing a suitable conductive material and a suitable etching process. For example, a material of the first conductive layer 301 and a material of the third conductive layer 303 all include transparent conductive materials such as indium tin oxide (ITO), indium zinc oxide (IZO) etc., and a material of the second conductive layer 302 includes a metal material such as silver (Ag), so that an etching rate of the second conductive layer 302 is different from etching rates of the first conductive layer 301 and the third conductive layer 303. That is, the materials of the first conductive layer 301 and the third conductive layer 303 are same, and the etching rates of the first conductive layer 301 and the third conductive layer 303 are greater than the etching rate of the second conductive layer 302.

In this way, under a same conventional etching process condition, due to the difference in the etching rates of the conductive layers, the second conductive layer 302 is more difficult to be etched than the first conductive layer 301 and the third conductive layer 303, so that the outer boundary of the etched the second conductive layer 302 exceeds the outer boundaries of the first conductive layer 301 and the second conductive layer 302.

Of course, in another embodiment, the material of the third conductive layer 303 can also be different from that of the first conductive layer 301, so that the etching rate of the third conductive layer 303 is different from the etching rates of the first conductive layer 301 and the second conductive layer 302, so as to make the auxiliary electrode 30 form a more complicated edge appearance. For other descriptions please refer to the embodiments mentioned above, and redundant description will not be mentioned herein again.

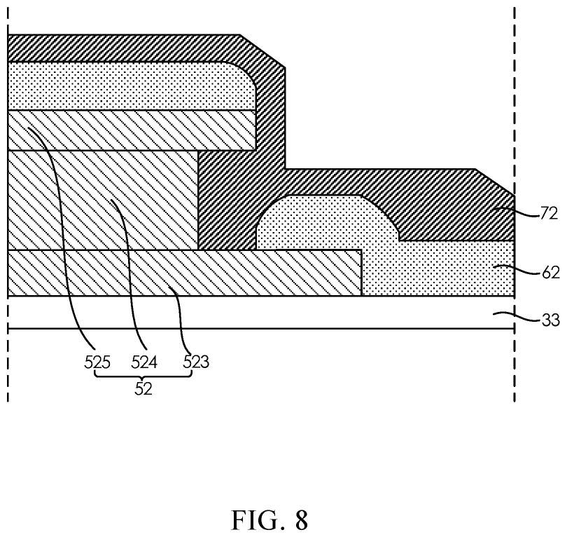

In one embodiment, please refer to FIG. 1 to FIG. 8. FIG. 8 is a schematic diagram of another sectional structure of the auxiliary electrode provided by one embodiment of the present application. The difference from the aforesaid embodiments is that the auxiliary electrode 30 includes the first conductive layer 301, the second conductive layer 302, and the third conductive layer 303 disposed in a stack, the second conductive layer 302 is located on a side of the first conductive layer 301 away from the planarization layer 11, and the orthogonal projection of the second conductive layer 302 on the base substrate 10 is within a range of an orthogonal projection of the third conductive layer 303 on the base substrate 10.

Specifically, the outer boundary of the first conductive layer 301 exceeds the outer boundary of the second conductive layer 302, the outer boundary of the third conductive layer 303 also exceeds the outer boundary of the second conductive layer 302, the second conductive layer 302 is indented relative to the first conductive layer 301 and the third conductive layer 303, so that the undercut structure is formed at the outer boundary of the third conductive layer 303 and the outer boundary of the second conductive layer 302, thereby making the organic light-emitting layer 40 to be more easily cut off at the edge of the auxiliary electrode 30. From another perspective, it can be understood that the undercut structure formed at the edge of the auxiliary electrode 30 is actually equivalent to protrusions or burrs.

Similarly, the edge appearance of the auxiliary electrode 30 can be formed by choosing a suitable conductive material and a suitable etching process. For example, a material of the first conductive layer 301 and a material of the third conductive layer 303 all include transparent conductive materials such as indium tin oxide (ITO), indium zinc oxide (IZO) etc., and a material of the second conductive layer 302 includes a metal material such as aluminum (Al), tungsten oxide (WOx), or an aluminum alloy, so that an etching rate of the second conductive layer 302 is different from etching rates of the first conductive layer 301 and the third conductive layer 303. That is, the materials of the first conductive layer 301 and the third conductive layer 303 are same, and the etching rates of the first conductive layer 301 and the third conductive layer 303 are less than the etching rate of the second conductive layer 302.

In this way, under a same general etching process condition, due to the difference in the etching rates of the conductive layers, the second conductive layer 302 is easier to be etched than the first conductive layer 301 and the third conductive layer 303, so that the outer boundary of the etched the second conductive layer 302 is indented relative to the outer boundaries of the first conductive layer 301 and the second conductive layer 302. For other descriptions please refer to the embodiments mentioned above, and redundant description will not be mentioned herein again.

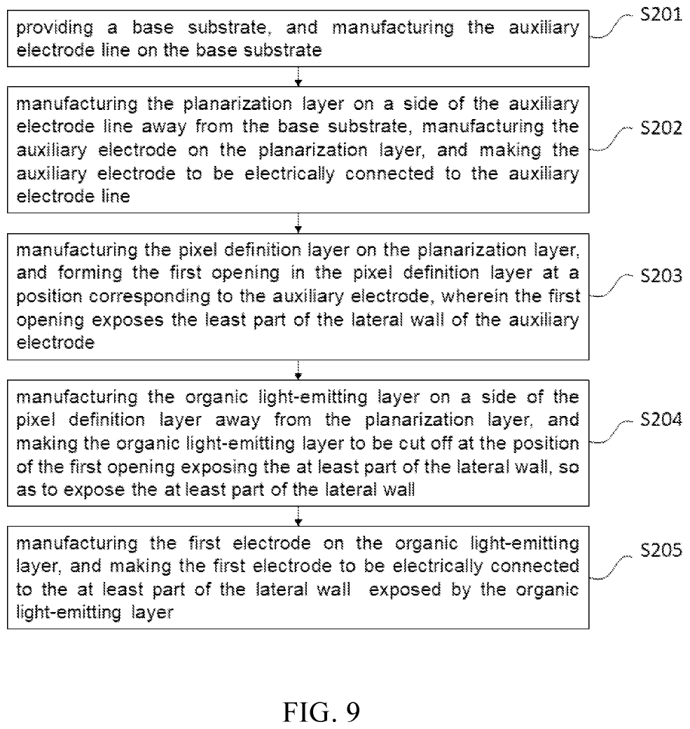

On the basis of the same invention construct, one embodiment of the present application further provides a manufacturing method of the display panel. Please refer to FIG. 1 to FIG. 15. FIG. 9 is a flowchart of the manufacturing method of the display panel provided by one embodiment of the present application. FIG. 10 to FIG. 15 are schematic diagrams of part film layer structures of the display panel manufactured by each step in the manufacturing method of the display panel provided by embodiments of the present application. As illustrated in FIG. 9, the manufacturing method of the display panel includes following steps.

S201: providing a base substrate 10, and manufacturing the auxiliary electrode line 20 on the base substrate 10.

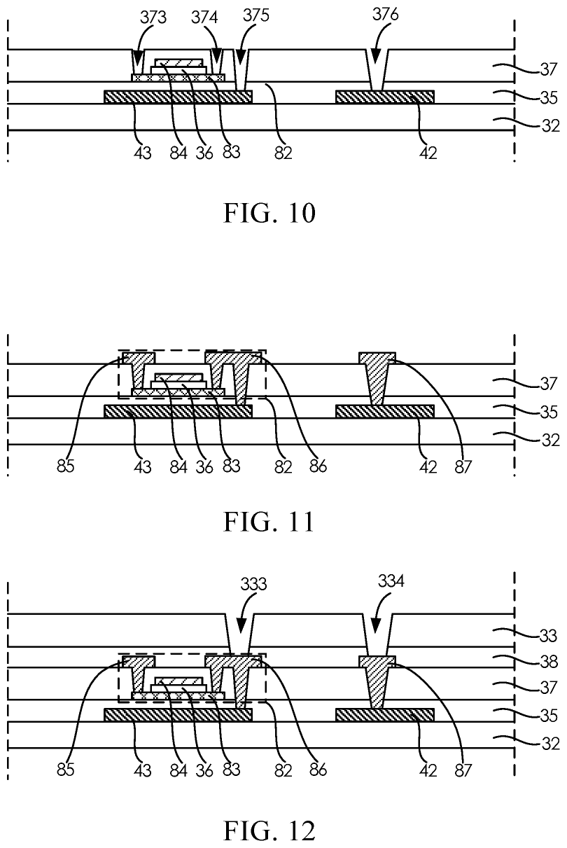

Specifically, please refer to FIG. 10 and FIG. 11. The auxiliary electrode line 20 and the light-shielding layer 21 are manufactured on the substrate 10, and the light-shielding layer 21 and the auxiliary electrode line 20 are disposed in a same layer.

The transistor 60 is manufactured on the base substrate 10. Specifically, the buffer layer 13 is manufactured on the base substrate 10, and the buffer layer 13 covers the light-shielding layer 21, the auxiliary electrode line 20, and the base substrate 10.

The active layer 61, the gate insulation layer 14, the gate electrode 62, and the interlayer insulation layer 15 are sequentially stacked and manufactured on the buffer layer 13. A first via hole 151, a second via hole 152, a third via hole 153, and a fourth via hole 154 are formed in the interlayer insulation layer 15.

The source electrode 63, the drain electrode 64 and the bridge electrode 65 are manufactured on the interlayer insulation layer 15. The source electrode 63 is electrically connected to the active layer 61 through the first via hole 151. The drain electrode 64 is electrically connected to the active layer 61 through the second via hole 152. Meanwhile, the drain electrode 64 is also electrically connected to the light-shielding layer 21 through the third via hole 153. The bridge electrode 65 is electrically connected to the auxiliary electrode line 20 through the fourth via hole 154.

S202: manufacturing the planarization layer 11 on a side of the auxiliary electrode line 20 away from the base substrate 10, manufacturing the auxiliary electrode 30 on the planarization layer 11, and making the auxiliary electrode 30 to be electrically connected to the auxiliary electrode line 20.

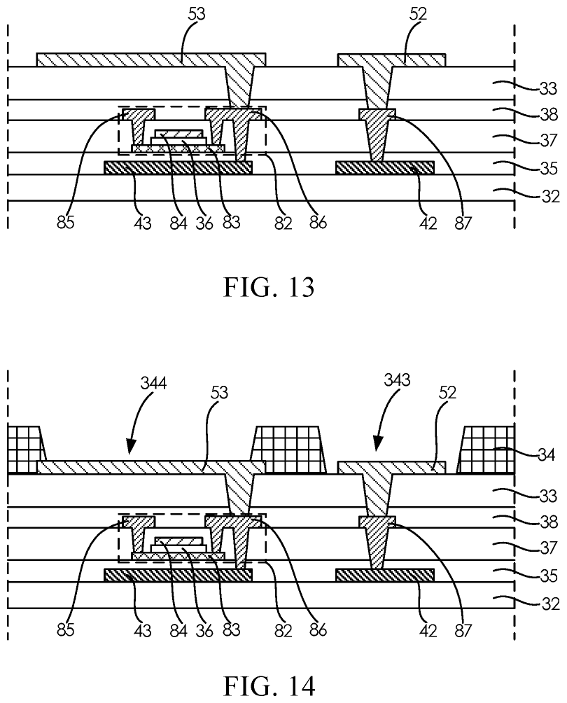

Specifically, please refer to FIG. 12 and FIG. 13. The passivation layer 16 and the planarization layer 11 are sequentially stacked on a side of the auxiliary electrode line 20 away from the base substrate 10. The passivation layer 16 covers the source electrode 63, the drain electrode 64, the bridge electrode 65, and the interlayer insulation layer 15. The planarization layer 11 covers on the passivation layer 16. A fifth via hole 111 and a sixth via hole 112 are formed in the planarization layer 11.

The auxiliary electrode 30 and the second electrode 31 are manufactured on the planarization layer 11, the second electrode 31 is connected to the drain electrode 64 through the fifth via hole 111, and the auxiliary electrode line 20 is electrically connected to the bridge electrode 65 through the sixth via hole 112, so as to realize the electrical connection between the auxiliary electrode 30 and the auxiliary electrode line 20. The slope angle “a” of the edge of the auxiliary electrode 30 close to the pixel definition layer 12 is greater than or equal to 90 degrees, so that the lateral wall 32 of the auxiliary electrode 30 forms a steep slope.

S203: manufacturing the pixel definition layer 12 on the planarization layer 11, and forming the first opening 121 in the pixel definition layer 12 at a position corresponding to the auxiliary electrode 30, wherein the first opening 121 exposes the least part of the lateral wall 32 of the auxiliary electrode 30.

Specifically, please refer to FIG. 14. The pixel definition layer 12 is manufactured on the planarization layer 11, the first opening 121 is formed at a position corresponding to the auxiliary electrode 30 in the pixel definition layer 12, and the second opening 122 is formed at a position corresponding to the second electrode 31. The first opening 121 exposes the at least part of the lateral wall 32 of the auxiliary electrode 30. In this embodiment, the first opening 121 exposing all the lateral wall 32 of the auxiliary electrode 30 is taken as an example for description. In this way, an orthogonal projection of the auxiliary electrode 30 on the base substrate 10 separates from an orthogonal projection of the pixel definition layer 12 on the base substrate 10, the auxiliary electrode 30 is disposed separated from the pixel definition layer 12. That is, the pixel definition layer 12 does not cover the edge of the auxiliary electrode 30, and there is a gap between the pixel definition layer 12 and the auxiliary electrode 30. The second opening 122 exposes a part of the second electrode 31, and the pixel definition layer 12 covers an edge of the second electrode 31.

S204: manufacturing the organic light-emitting layer 40 on a side of the pixel definition layer 12 away from the planarization layer 11, and making the organic light-emitting layer 40 to be cut off at the position of the first opening 121 exposing the at least part of the lateral wall 32, so as to expose the at least part of the lateral wall 32.

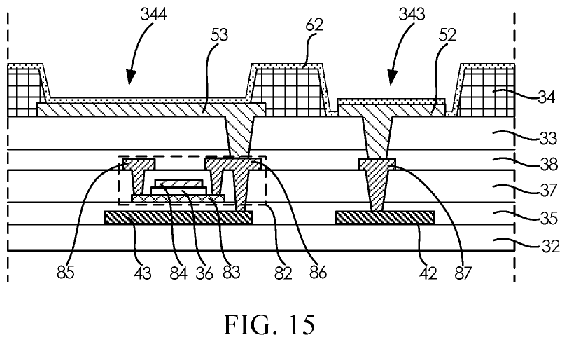

Specifically, please refer to FIG. 15. The organic light-emitting layer 40 is manufactured on the side of the pixel definition layer 12 away from the planarization layer 11 by an evaporation process, etc. The organic light-emitting layer 40 covers on the pixel definition layer 12, the second electrode 31, and the auxiliary electrode 30. However, because the edge of the auxiliary electrode 30 has the steep slope, the organic light-emitting layer 40 is cut off at the edge of the auxiliary electrode 30. That is, the organic light-emitting layer 40 is cut off at the position of the at least part of the lateral wall 32 exposed by the first opening 121, so as to expose the at least part of the lateral wall 32.

S205: manufacturing the first electrode 50 on the organic light-emitting layer 40, and making the first electrode 50 to be electrically connected to the at least part of the lateral wall 32 exposed by the organic light-emitting layer 40.

Specifically, please refer to FIG. 4. The first electrode 50 is manufactured on the organic light-emitting layer 40 by a sputtering process, and the first electrode 50 covers the organic light-emitting layer 40 and covers at least part of the lateral wall 32 of the auxiliary electrode 30 exposed by the organic light-emitting layer 40, so as to realize the direct contact between the first electrode 50 and the auxiliary electrode 30, thereby realizing the electrical connection between the first electrode 50 and the auxiliary electrode line 20.

On the basis of the same invention construct, the present application further provides an electronic device, which includes a housing and the display panel of one of the aforesaid embodiments. The display panel is assembled in the housing. The electronic device includes an electronic display product such as a television, a mobile phone, a computer etc.

According to embodiments mentioned above:
the present application provides the display panel and the electronic device; in the display panel, by deposing an auxiliary electrode in the first opening of the pixel definition layer, the first electrode is electrically connected to the auxiliary electrode line through the auxiliary electrode, so as to reduce a resistance of the first electrode. Therefore, uneven display due to voltage drop is remedied, so that a problem of large cathode resistance existing in a current display panel is relieved. Meanwhile, the first opening of the pixel definition layer of the present application exposes the part of the lateral wall of the auxiliary electrode. The organic light-emitting layer is cut off at the position of the first opening exposing the at least part of the lateral wall, so as to expose the at least part of the lateral wall. The first electrode is electrically connected to the at least part of the lateral wall exposed by the organic light-emitting layer. Therefore, the first electrode is able to be directly contacted to and be electrically connected to the lateral wall of the auxiliary electrode, thereby reducing a contact resistance between the first electrode and the auxiliary electrode, and further remedying uneven display due to voltage drop.

In the above embodiments, the description of each embodiment has its emphasis, and for some embodiments that may not be detailed, reference may be made to the relevant description of other embodiments.

The embodiments of present application are described in detail above. This article uses specific cases for describing the principles and the embodiments of the present application, and the description of the embodiments mentioned above is only for helping to understand the method and the core idea of the present application. It should be understood by those skilled in the art, that it can perform changes in the technical solution of the embodiments mentioned above, or can perform equivalent replacements in part of technical characteristics, and the changes or replacements do not make the essence of the corresponding technical solution depart from the scope of the technical solution of each embodiment of the present application.

What is claimed is:

1. A display panel, comprising:
a base substrate;
an auxiliary electrode line disposed on the base substrate;
a planarization layer disposed on a side of the auxiliary electrode line away from the base substrate;
an auxiliary electrode disposed on the planarization layer and electrically connected to the auxiliary electrode line;
a pixel definition layer disposed on the planarization layer, wherein a first opening is defined at a position corresponding to the auxiliary electrode in the pixel definition layer, and the first opening exposes at least part of a lateral wall of the auxiliary electrode;
an organic light-emitting layer covering a side of the pixel definition layer away from the planarization layer, and being cut off at a position of the first opening exposing the at least part of the lateral wall, so as to expose the at least part of the lateral wall; and
a first electrode covering on the organic light-emitting layer and electrically connected to the at least part of the lateral wall exposed by the organic light-emitting layer.

2. The display panel as claimed in claim 1, wherein the auxiliary electrode comprises at least one first conductive layer and at least one second conductive layer disposed in a stack, an orthogonal projection of one conductive layer of the first conductive layer and the second conductive layer being adjacent to each other on the base substrate is within a range of an orthogonal projection of another conductive layer on the base substrate.

3. The display panel as claimed in claim 2, wherein the auxiliary electrode comprises at least one third conductive layer, the second conductive layer is located between the first conductive layer and the third conductive layer, an orthogonal projection of one conductive layer of the second conductive layer and the third conductive layer being adjacent to each other on the base substrate is within a range of an orthogonal projection of another conductive layer on the base substrate.

4. The display panel as claimed in claim 3, wherein the auxiliary electrode comprises the first conductive layer, the second conductive layer, and the third conductive layer disposed in a stack, the second conductive layer is located on a side of the first conductive layer away from the planarization layer, and an orthogonal projection of the first conductive layer on the base substrate is within a range of an orthogonal projection of the second conductive layer on the base substrate.

5. The display panel as claimed in claim 4, wherein a material of the first conductive layer and a material of the third conductive layer comprise indium tin oxide (ITO) or indium doped zinc oxide (IZO), and a material of the second conductive layer comprises silver (Ag).

6. The display panel as claimed in claim 3, wherein the auxiliary electrode comprises the first conductive layer, the second conductive layer, and the third conductive layer disposed in a stack, the second conductive layer is located on a side of the first conductive layer away from the planarization layer, and an orthogonal projection of the second conductive layer on the base substrate is within a range of an orthogonal projection of the third conductive layer on the base substrate.

7. The display panel as claimed in claim 6, wherein a material of the first conductive layer and a material of the third conductive layer comprise indium tin oxide (ITO) or indium doped zinc oxide (IZO), and a material of the second conductive layer comprises aluminum (Al), tungsten oxide (WOx), or an aluminum alloy.

8. The display panel as claimed in claim 1, wherein a slope angle of the lateral wall is greater than or equal to 90 degrees.

9. The display panel as claimed in claim 1, wherein an orthogonal projection of the auxiliary electrode on the base substrate separates from an orthogonal projection of the pixel definition layer on the base substrate.

10. The display panel as claimed in claim 1, wherein the display panel comprises a second electrode disposed on the planarization layer, the organic light-emitting layer is located between the second electrode and the first electrode, and the second electrode and the auxiliary electrode are disposed in a same layer.

11. The display panel as claimed in claim 10, wherein the display panel comprises a transistor disposed on the base substrate, the second electrode is located on a side of the transistor away from the base substrate, the second electrode is electrically connected to the transistor, and
the transistor comprises an active layer, a gate electrode, a source electrode, and a drain electrode; and
wherein the display panel comprises a bridge electrode, the auxiliary electrode is electrically connected to the auxiliary electrode line through the bridge electrode, and the bridge electrode and at least one of the active layer, the gate electrode, the source electrode, or the drain electrode are disposed in a same layer.

12. The display panel as claimed in claim 11, wherein the display panel comprises a light-shielding layer disposed on the base substrate, the light-shielding layer is located between the transistor and the base substrate and is disposed corresponding to the active layer, and the auxiliary electrode line and the light-shielding layer are disposed in a same layer.

13. An electronic device, comprising a housing and the display panel as claimed in claim 1, wherein the display panel is assembled in the housing.
